(19) United States
(12) Patent Application Publication
(10) Pub. No.: US 2013/0321092 A1
(43) Pub. Date: Dec. 5, 2013

(54) HYBRID ACTIVE TUNING SYSTEMS AND METHODS

(71) Applicant: Maury Microwave, Inc., Ontario, CA (US)

(72) Inventor: Gary R. Simpson, Fontana, CA (US)

(73) Assignee: Maury Microwave, Inc., Ontario, CA (US)

(21) Appl. No.: 13/903,399

(22) Filed: May 28, 2013

Related U.S. Application Data
(60) Provisional application No. 61/659,931, filed on Jun. 14, 2012.
(60) Provisional application No. 61/652,782, filed on May 29, 2012.

(51) Int. Cl. H03H 11/30

(52) U.S. Cl. CPC H03H 11/30
USPC 333/17.3

(57) ABSTRACT

An impedance tuner system that uses at least one passive tuner and at least one active tuner to control one or more impedances at a reference plane or planes. Each of the at least one active tuners operates at a target frequency at which the impedance is to be controlled. The passive tuner is set to a passive tuner target impedance before active tuners are set to their target impedances.

### CROSS-REFERENCE TO RELATED PATENT APPLICATIONS

This application is a non-provisional application of, and claims priority from, provisional U.S. patent application Ser. No. 61/659,931, filed Jun. 14, 2012, and provisional U.S. patent application Ser. No. 61/652,782, filed May 29, 2012, the entire contents of which applications are incorporated herein by reference.

### BACKGROUND

Passive load pull systems have been widely used to characterize microwave devices. Load pull involves measuring a Device Under Test (DUT) under controlled conditions, including controlled impedances seen by the DUT. The controlled impedances may include the impedance on any port of the DUT, and they may be at the fundamental operating frequency or at a harmonic frequency. A typical load pull measurement would measure the DUT performance at multiple impedances to show the effect of impedance on the DUT performance. Some other conditions that may be controlled and/or varied include frequency, power level, bias values, or temperature.

In this document, impedance, reflection, or reflection coefficient are all used as general terms to describe the RF termination seen at an RF port. They are functions of the signal coming out of an RF port and the signal at the same frequency coming into the port. Reflection coefficient is related to impedance by the expression

$$Z = {Z}_{0} \frac{( 1 + Γ )}{( 1 - Γ )}$$

where Z is the impedance and F is the reflection coefficient. Both terms contain the same information, so that if one is known, the other is also known. Therefore, in this document they will be used interchangeably. Also, the terms “RF port” and “reference plane” are used interchangeably in the context of impedance control.

Active tuning load pull systems have also been used, but not widely because of the complexity and cost. Active tuning provides some advantages, including capability to present a higher reflection coefficient than is possible with a passive tuning system, even with fixture losses or other circuit losses. The impedance seen by the DUT can be all the way to the edge of the Smith chart, and even outside the Smith chart, if desired.

In this document, a “tuner system” will refer to a RF measurement system which uses some kind of tuner or tuners to control impedance at a reference plane or planes, e.g. an impedance seen by a DUT.

An “automated tuner” may be computer controlled; a “manual tuner” is controlled manually by the user.

A “passive tuner” controls the impedance at a reference plane with a passive reflection. This means that it reflects a portion of a signal coming out of a port back into that port. It controls the magnitude or phase of the reflected signal by changing RF hardware settings. The maximum reflection is limited by the physical hardware and losses between the tuner and the reference plane.

An “active tuner” controls an impedance at a reference plane by feeding a signal back to that reference plane with a specific magnitude and phase relative to the signal from that reference plane. In the context of conducting measurements on a DUT, the active tuner controls the impedance seen by the DUT by feeding a signal back to the DUT with a specific magnitude and phase relative to the signal from the DUT. It would normally use a signal that is either generated or amplified external to the DUT. The impedance seen by the DUT will be based on the “active” signal fed back to the DUT. The active tuner is said to be operating, or controlling the impedance, at the frequency of the “active” signal. In principle, the maximum effective reflection can be up to or even greater than unity. In practice, this is limited by the amount of power generated by the measurement system that can be fed back to the DUT to synthesize that impedance.

### BRIEF DESCRIPTION OF THE DRAWINGS

Features and advantages of the disclosure will readily be appreciated by persons skilled in the art from the following detailed description when read in conjunction with the drawing wherein:

FIG. 1 shows the principle of reflection, in this case done with a passive tuner.

FIG. 2 shows how the reflection coefficient can be plotted on a polar chart as a vector with magnitude and phase.

FIG. 3 shows one method of active tuning, which is to use a separate RF source to create a signal that is injected back to the DUT.

FIG. 4 shows an alternate method of active tuning, using a loop type active tuner.

FIG. 5 shows another alternate method of active tuning, which samples the output signal from the DUT, and then uses a passive tuner to control the magnitude and phase of the amplified signal before it is injected back to the DUT.

FIG. 6 shows one form of a hybrid tuning system.

FIG. 7 shows how the reflection coefficient, plotted on a polar chart, is a combination of two vectors, both with magnitude and phase.

FIG. 8 shows another form of a hybrid tuning system.

FIG. 9 shows a hybrid tuning system with passive tuners on 2 ports of a DUT, plus six separate RF sources.

FIG. 10 shows one approach to connecting a separate source for active tuning.

FIG. 11 shows another approach to connecting a separate source for active tuning.

FIG. 12 shows another approach to connecting a separate source for active tuning.

FIG. 13 illustrates a schematic diagram of a test setup for performing passive tuning on a first port of a DUT, and hybrid tuning on a second port of the DUT.

FIG. 14-16 illustrate schematic diagrams of alternate test setups for performing passive tuning on a first port of a DUT, and hybrid tuning on a second port of the DUT.

FIG. 17 illustrates a schematic diagram of a test setup for passive tuning on a first port of a DUT, and hybrid tuning on a second port of the DUT, with two active tuning signals injected in front of the passive tuner on the second port of the DUT.

FIG. 18 illustrates a schematic diagram of a test setup for passive tuning on a first port of a DUT, and hybrid tuning on a second port of the DUT, with two active tuning signals injected in front of the passive tuner and one active tuning signal injected behind the passive tuner on the second port of the DUT at different frequencies.

FIG. 19 illustrates a schematic diagram of a test setup for passive tuning on a first port of a DUT, and hybrid tuning on a second port of the DUT, with three active tuning signals of different frequencies injected into a multiplexer, with separate hybrid tuning for each frequency.

FIG. 20 illustrates a schematic diagram of a test setup for passive tuning on a first port of a DUT, and hybrid tuning on a second port of the DUT, with three active tuning signals of different frequencies, injected into a multiplexer behind the passive tuner on the second port of the DUT.

FIG. 21 illustrates a schematic diagram of a test setup for passive tuning on a first port of a DUT, and hybrid tuning on a second port of the DUT, with two active tuning signals of different frequencies combined and then injected in front of the passive tuner on the second port of the DUT.

FIG. 22 illustrates a schematic diagram of a test setup for passive tuning on a first port of a DUT, and hybrid tuning on a second port of the DUT, with one active tuning signal injected behind the passive tuner, and two active tuning signals combined and injected in front of the passive tuner on the second port of the DUT.

FIG. 23 is a schematic block diagram illustrating a controller for the test setup of FIG. 17.

FIG. 24 is a flow diagram of an exemplary method for hybrid tuning.

FIG. 25 is a flow diagram of an exemplary process for setting one passive tuner to a target impedance.

FIG. 26 is a flow diagram of an exemplary process for setting one active tuner to a target impedance.

### DETAILED DESCRIPTION

In the following detailed description and in the several figures of the drawing, like elements are identified with like reference numerals. The figures are not to scale, and relative feature sizes may be exaggerated for illustrative purposes.

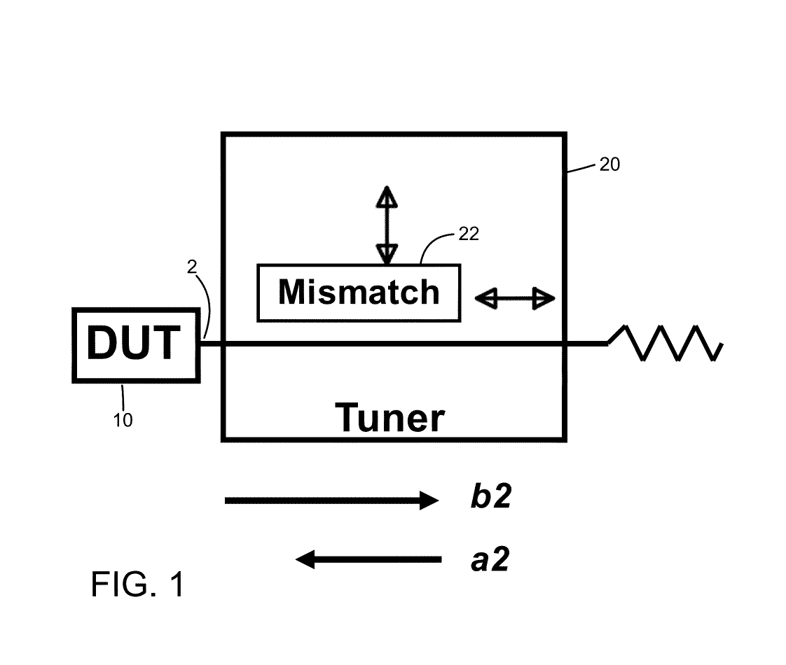

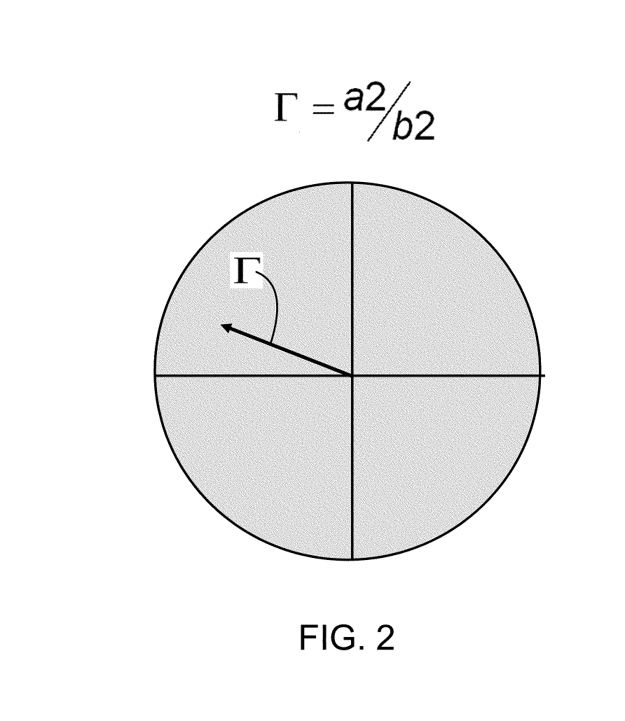

FIG. 1 shows the principle of reflection, in this case done with a passive tuner 20. A signal comes out of the DUT 10 (in this case port 2 of the DUT). This output signal, called b2, encounters a mismatch 22, and a portion of that b2 signal is reflected back toward the DUT. This reflected signal is called a2. The ratio of a2/b2 is the reflection coefficient. The mismatch is variable, which is what makes it a passive tuner. In a passive slide screw tuner, for example, a mismatch probe moves vertically to change the magnitude of the mismatch, and moves horizontally to change the phase of the mismatch. FIG. 2 shows how the reflection coefficient can be plotted on a polar chart as a vector with magnitude and phase.

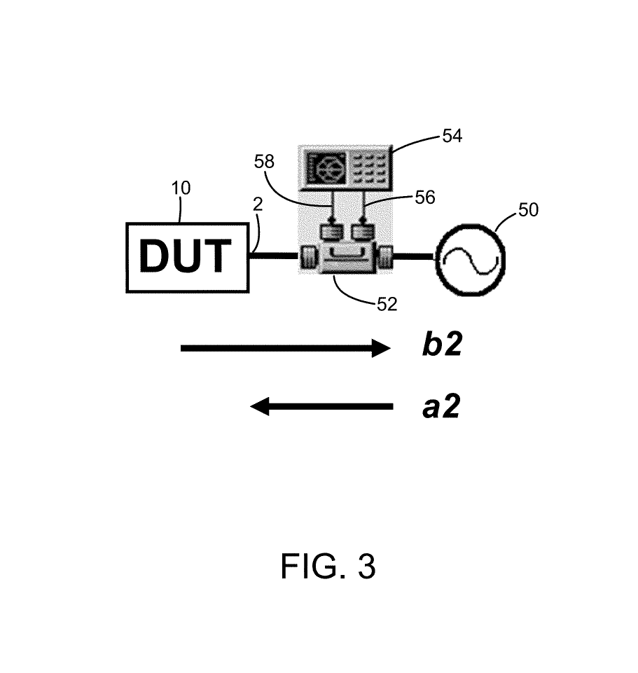

FIG. 3 shows one method of active tuning, which is to use a separate RF source 50 to create a signal that is injected back to the DUT 10. The b2 vector represents the signal coming out of port 2 of the DUT, and the a2 vector represents the signal coming back into port 2 of the DUT. The ratio of a2/b2 is the reflection coefficient.

Note that FIG. 3 includes a coupler 52 and receiver 54. In this example, the coupler samples the a2 and b2 separately, and the cables 56, 58 from the coupler connect to the receiver which can then measure them. The coupler and receiver are not part of the active tuner, but allow the a2 and b2 signals, or at least their ratio to be measured. The coupler and receiver may be used with passive tuning or active tuning. A network analyzer is commonly used as a receiver, and error correction is commonly used to improve the accuracy of the a2 and b2 signal measurement.

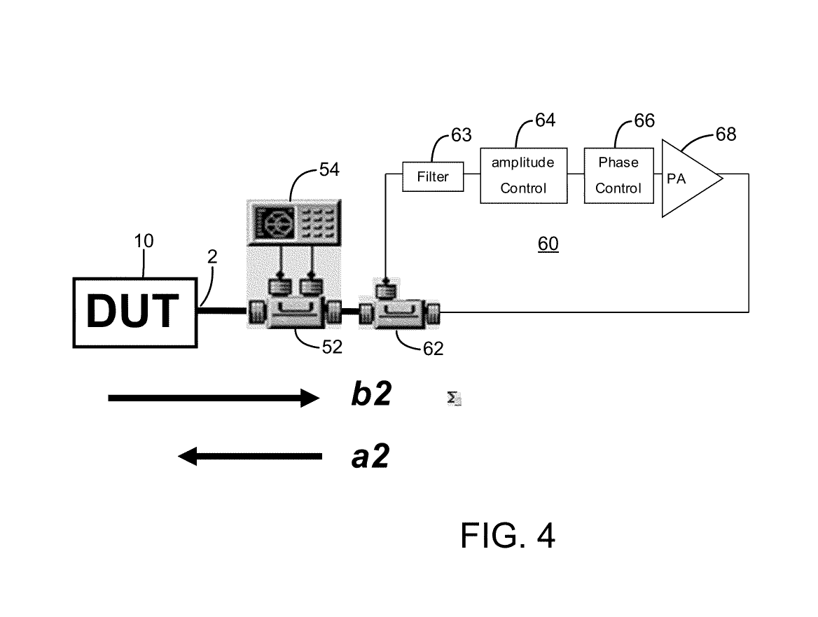

FIG. 4 shows an alternate method of active tuning, using a loop type active tuner. This method employs a loop 60, which samples the output signal from the DUT with a coupler 62, and then typically amplifies (68) and adjusts the amplitude (by amplitude control 64, such as a variable attenuator) and phase (by phase control 66, such as a variable phase shifter) of the sampled signal, and then feeds it back to the DUT. A filter 63 such as a bandpass filter may be included to allow only signals of a desired frequency range to enter the loop, e.g., passing only a first harmonic frequency while blocking the harmonics.

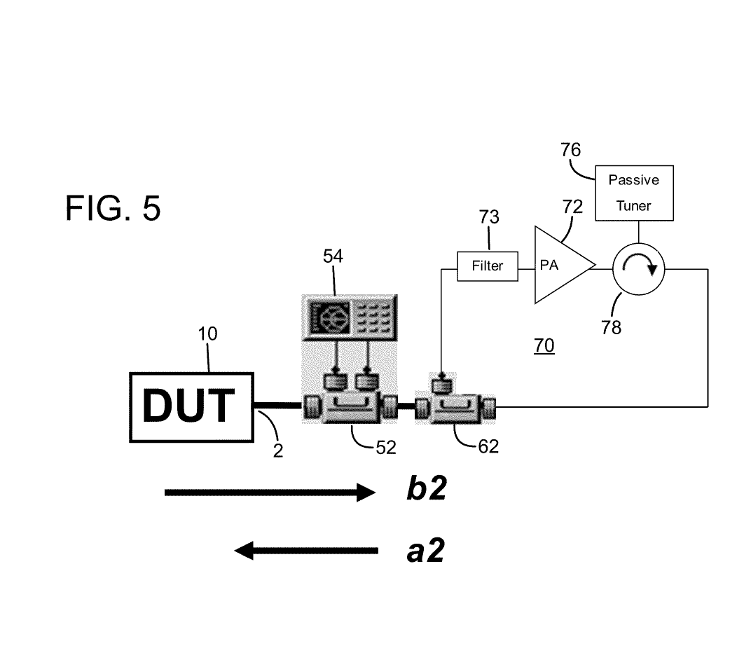

FIG. 5 shows another alternate method of active tuning, which samples the output signal from the DUT 10 with coupler 62, and then uses a passive tuner 76 to control the magnitude and phase of the amplified signal before it is injected back to the DUT. This is also a loop type active tuner 70. The active tuner may include an amplifier 72, connected in the loop with a three port circulator 78. A bandpass filter 73 may also be included. In this case, the passive tuner 76 is not used as a tuner from the DUT perspective, but as a component of the active tuner, performing the functions of the amplitude control 64 and phase control 66 of the system of FIG. 4. Therefore, this is an example of active tuning only, not passive tuning or hybrid tuning.

An aspect involves combining passive tuning with active tuning to create a hybrid active tuning system. Another aspect includes tuning impedance at frequencies which are not harmonically related to the fundamental frequency.

Passive tuner systems and active tuning systems each use different approaches to creating the RF termination “seen” by a port. Each type of system has some advantages and some disadvantages relative to the other type. So load pull measurement systems in the past have been setup to be passive load pull systems or active load pull systems, depending on the needs of the application. The two types of systems have been used separately for many years.

In the prior art, it has been common to do load pull where the impedances at the fundamental and harmonic frequencies are controlled.

Aspects of the hybrid tuning systems and methods described herein combine passive tuning with active tuning to achieve some of the advantages of both types of systems.

As described above, there are different approaches to active tuning. The two most common are the separate source approach and the loop approach. Both methods have been used and published in the literature. There are also other approaches to active tuning that are less common, such as splitting the drive source, and using part to drive the DUT, and amplifying the other part and feeding it into the DUT output as an active tuning injection signal.

The separate source active tuning approach is generally the simplest active tuning setup. A separate source is connected directly, or through an isolator or coupler. Multiple separate sources may be combined to actively tune the impedance at multiple frequencies. In the past, the multiple tuned frequencies would be harmonically related. For example, the second harmonic would be two times the fundamental frequency, and the third harmonic would be three times the fundamental frequency.

With the separate source approach to active tuning, if the b2 output signal from the DUT changes, then the signal from the separate source must be adjusted to maintain the same impedance. As is well known in the industry, a software loop is typically used to do this. An advantage of this approach is that RF oscillations typically cannot occur because the a2 signal does not track the b2 signal at the speed of the RF frequency.

The loop approach to active tuning samples the output from the DUT, and usually amplifies and controls the magnitude and phase of the sampled system. The advantage of this approach is that the impedance will stay constant as the b2 output signal from the DUT changes. A possible disadvantage is that the loop can oscillate.

In the prior art, passive tuners have been used as control elements in an active tuner, as shown in FIG. 5. In that case, the passive tuner was not used as a passive tuner, and did not reflect RF power passively back to the DUT. It was used to control the magnitude or phase of an amplified signal to be injected back into the DUT for active tuning. In that case, the circuit 70 was an active tuner, not a passive tuner, even though a passive tuner was used to control it.

Some of the advantages of passive tuning include simplicity, high power, and lower cost since power amplifiers are not required to generate the impedance. Some disadvantages may include a limitation on the possible reflection coefficient, inability to overcome losses between the tuner and the DUT, and the time to move the tuning elements when changing the impedance. Adding tuning at harmonic frequencies can make the setup mechanically complex.

Some of the advantages of active tuning include the ability to generate high reflections, to overcome losses between the tuner and the DUT, and speed of tuning. Adding tuning at harmonic frequencies is often fairly simple. Some disadvantages may include power limitations, high cost, or oscillations in the case of some loop type active tuners.

Hybrid tuning as described herein can combine some of the advantages of both. It can be fairly low cost, work at high power, overcome losses between the tuner and DUT, and adding tuning at harmonic frequencies can be fairly simple. Hybrid tuning can reduce the need for high power amplification in the active tuner. The reduction in power from the active tuner may occur because the passive tuner is reflecting substantial power at the fundamental frequency, and so if the active tuner is operating at the fundamental frequency, it does not have to provide the same power level output as the DUT, but only enough to make up what the passive tuner reflection does not provide, for an exemplary tuning application.

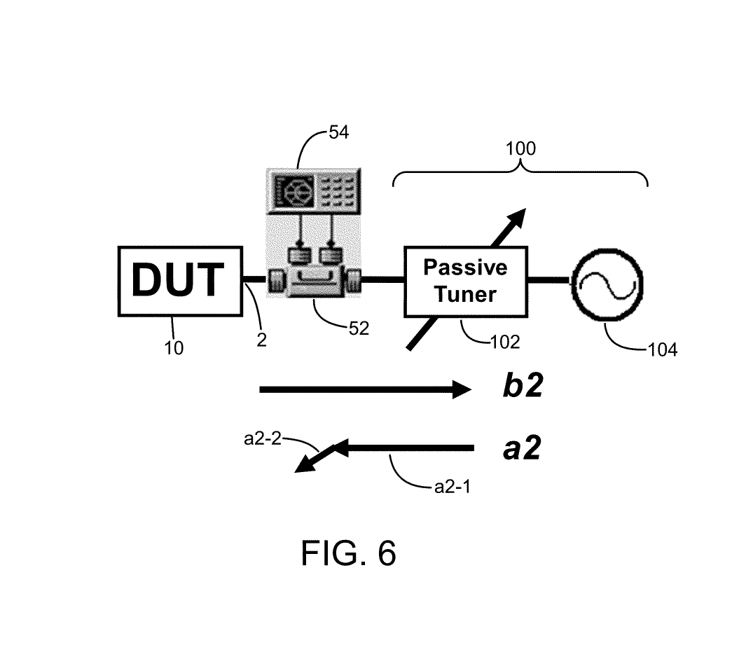

One exemplary setup is to use a passive tuner to reflect the high power out of a DUT at the fundamental frequency, and use active tuning with lower power to augment the a2 signal to get higher reflection at the fundamental. FIG. 6 shows one form of a hybrid tuning system 100. This combines a passive tuner 102 with the active tuning using a separate RF source 104 to inject a signal for the active tuning. The passive tuner 102 reflects some of the b2 signal from the DUT to an a2-1 signal, and the separate RF source 104 injects another signal as another a2-2 signal. If the two a2 signals are at the same frequency, they will combine to create the total a2 signal. The two a2 signals may be at different frequencies, in which case the passive tuner 102 will tune the impedance at one frequency, and the active tuner 104 will tune the impedance at another frequency. In this case, however, both frequencies are frequencies at which some power is output from the DUT. For example, the passive tuner may tune the impedance to the DUT fundamental frequency, and the active tuner may tune the impedance at a second harmonic frequency. Or, as another example, the passive tuner may tune the impedance to the third harmonic, and the active tuner tunes the impedance to the second harmonic frequency.

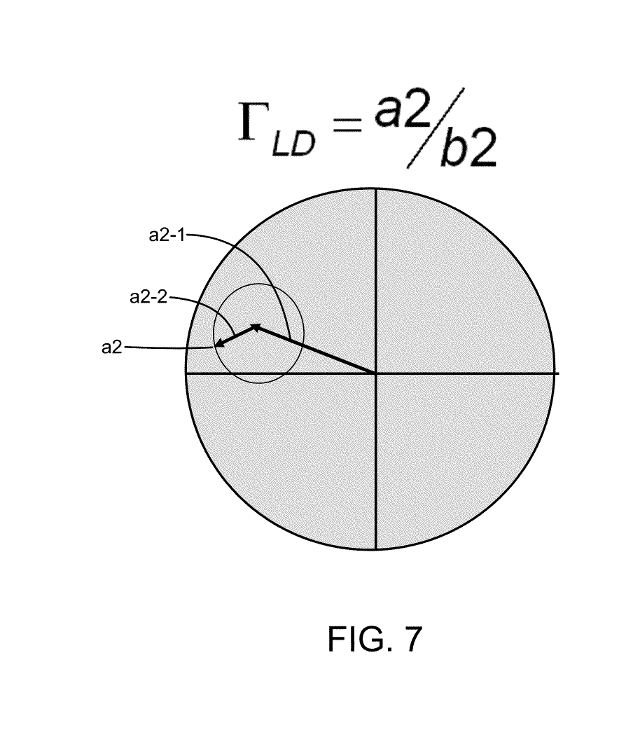

FIG. 7 shows how the reflection coefficient, plotted on a polar chart, is a combination of two vectors, both with magnitude and phase. The first vector, starting from the center of the chart, is the reflection (a2-1) from the passive tuner 102. The second vector a2-2 is from the active tuner, starts at the end of the first vector, and will land somewhere on a circle surrounding the end of the first vector, depending on the phase of the active injected signal compared to the passive reflected signal. FIG. 7 illustrates the case in which both the passive and active tuners are tuning an impedance at the same frequency.

Another exemplary hybrid tuning setup is to use a passive tuner to reflect the high power out of a DUT at the fundamental frequency, and use active tuning to tune the impedance at a harmonic frequency, where the power from the DUT is lower. Thus, in this example, the system of FIG. 6 may be employed, in which the external source 104 is controlled to provide an active signal at a harmonic of the signal b2 exiting the DUT 10.

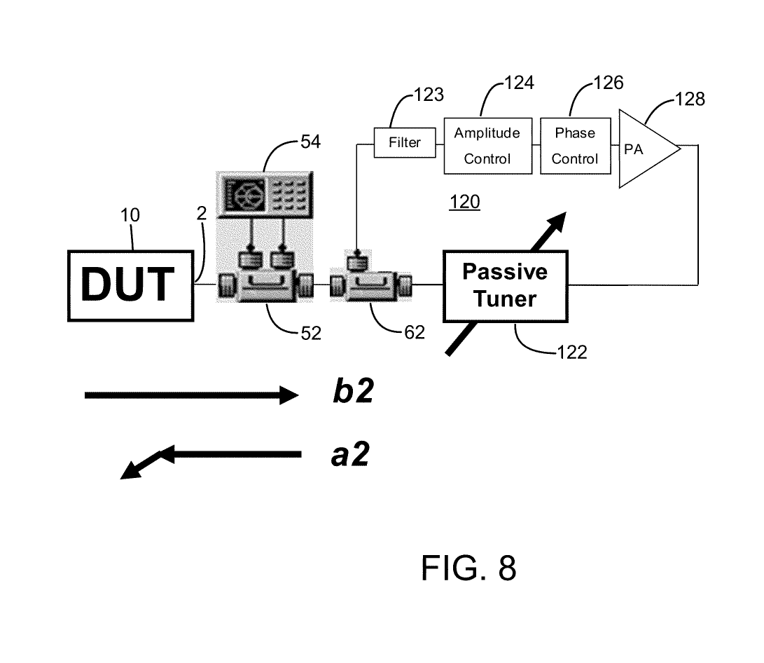

FIG. 8 shows another form of a hybrid tuning system. This combines a passive tuner 122 with a loop type active tuner 120. In this exemplary embodiment, a coupler 62 provides a coupled component of the signal from the DUT 10 to the loop, where the amplitude and phase of the signal component, filtered by bandpass filter 123 if needed, are controlled by amplitude control 124 and phase control 126, and amplified by power amplifier (PA) 128. The PA may be used in applications to overcome power losses in the couplers, passive tuner and the transmission lines, for example. For some low power applications, the PA may be omitted. The loop signal then passes through the passive tuner 122.

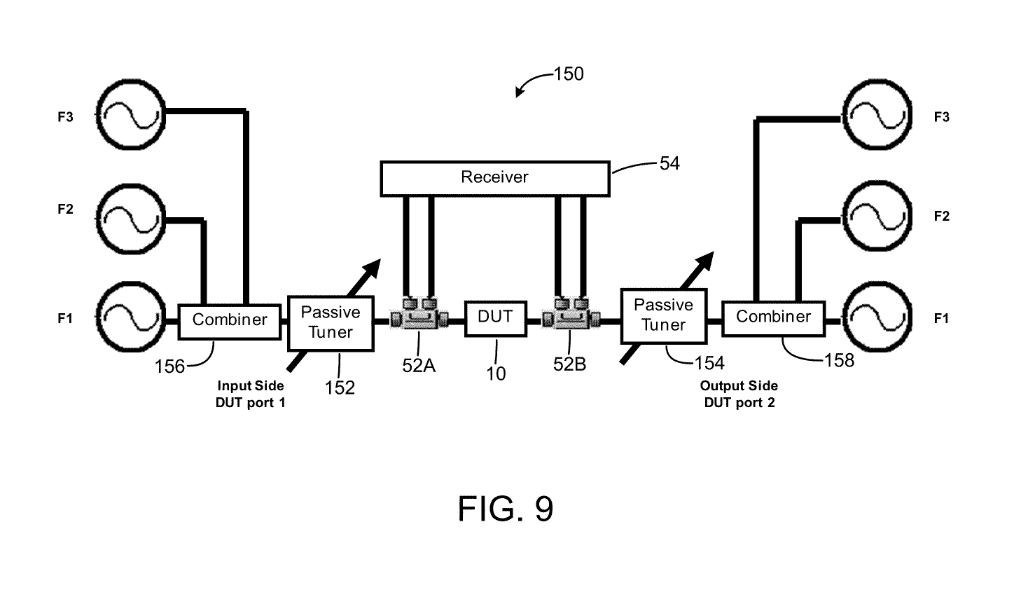

FIG. 9 shows a hybrid tuning system 150 with passive tuners 152, 154 on 2 ports of a DUT 10, plus six separate RF sources. On the DUT input side, the signals from sources F1, F2, F3 are combined at signal combiner 156, and passed into passive tuner 152. On the DUT output side, the signals from output sources F1, F2, F3 are combined at signal combiner 158, and passed into passive tuner 154. The F1 source on the input side provides a drive signal for the DUT 10. The F2 and F3 RF sources on the input side and all three RF sources on the output side are used for active tuning. In this example, the output F1 active tuner could augment the fundamental tuning with the passive tuner 154 on the output side, and the F2 and F3 separate sources on the output side could actively tune the second harmonic and third harmonic output impedances, respectively.

The F2 and F3 sources on the input side could actively tune the second harmonic and third harmonic input impedances, respectively. Alternatively, any of the active tuning sources could tune impedances at frequencies at which the DUT puts out some power that are not harmonically related to the fundamental frequency. In this exemplary case, the fundamental frequency is the drive frequency F1 on the input side.

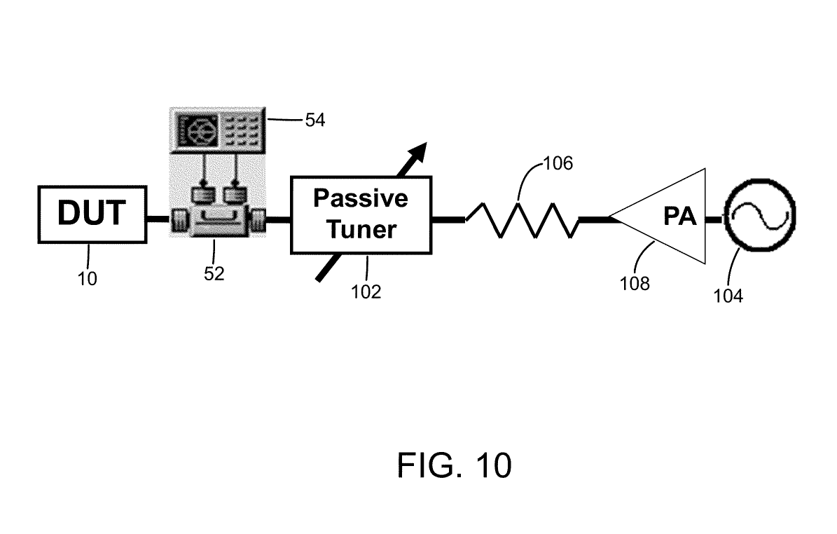

FIG. 10 shows one approach to connecting a separate source 104 for active tuning in a hybrid tuning system including a passive tuner 102. The optional attenuator 106 is to protect the power amplifier (PA) 108 that may be part of the active tuning.

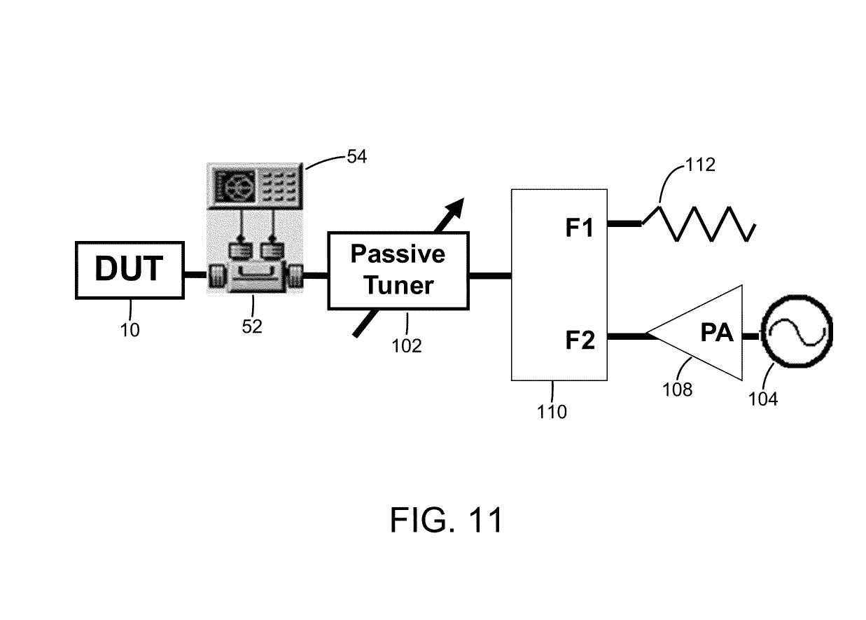

FIG. 11 shows another approach to connecting a separate source 108 for active tuning in a hybrid tuning system including a passive tuner 102. In this example, filters in a bidirectional diplexer 110 separate the fundamental and harmonic signals from the DUT 10. The fundamental signal F1 is terminated in a fixed load 112, and the harmonic signal F2 goes to the active tuner comprising source 104 and PA 108. The harmonic signal F2 is normally much smaller than the fundamental signal F1, so a low power PA is used for the active harmonic tuning. The PA might be damaged if the fundamental power from the DUT reaches it, so the diplexer filter protects the PA from the high fundamental power without limiting its ability to tune at the harmonic frequency.

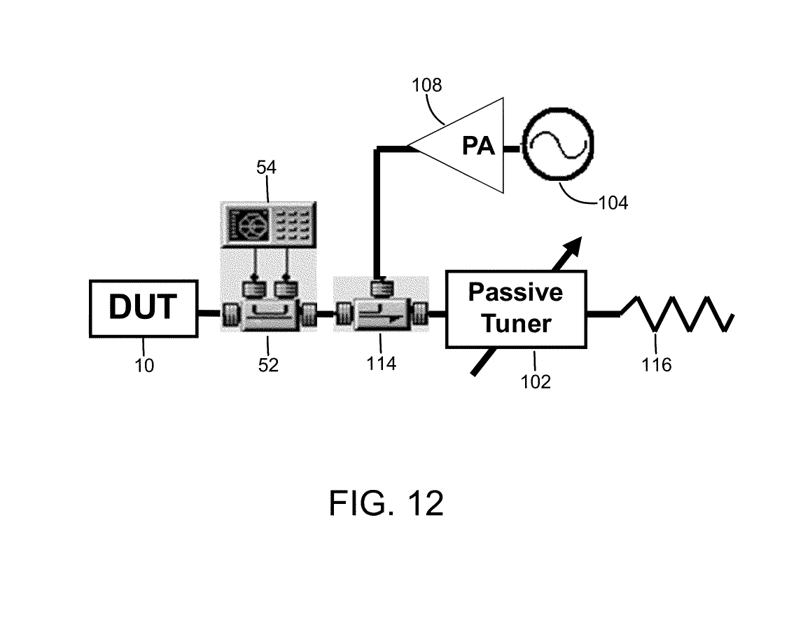

FIG. 12 shows another approach to connecting a separate source for active tuning in a hybrid tuning system including a passive tuner 102. The active tuning signal from the source 104 and PA 108 is injected though a coupler 114 between the DUT 10 and the passive tuner 102. An example of when this approach might be useful is when the passive tuner is tuning the fundamental frequency but also has a high loss or mismatch at the harmonic. Here, the PA 108 should be large enough to overcome coupling loss, but that loss does not depend so much on the loss of the passive tuner.

Another exemplary hybrid tuning setup, using the system of FIG. 8, for example, is to use a passive tuner 122 to reflect the high power out of a DUT 10 at the fundamental frequency, and use an active loop tuner 120 to tune a separate frequency which is not harmonically related to the fundamental frequency. An exemplary choice would be to tune impedance at a frequency where the DUT might otherwise oscillate in order to suppress the oscillation.

Another exemplary setup is to use active tuning to tune the source harmonic impedances if the DUT is putting out some power at those harmonics. In this case, the fundamental source impedance could be tuned with a passive tuner. The load impedance could be tuned with a passive tuner or tuners, an active tuner or tuners, or with hybrid tuning.

There are many combinations of hybrid tuning that can be used. If the DUT has more than one port, then passive tuning may be used on some ports, and active or hybrid tuning on other ports. Or hybrid tuning may be used on all ports. The passive and active tuners may operate at one frequency, or at different frequencies at which the DUT is putting out some power. The complete system, including tuning at multiple DUT ports, may include multiple frequencies, where at some frequencies or DUT ports the passive and active tuning may operate together in hybrid fashion and at other frequencies they may be used separately. The foregoing lists some exemplary combinations, but is not an exhaustive list.

An exemplary DUT could be a 1-port device, such as an oscillator. It could be a 2-port device, such as a power transistor or amplifier. It could be a 3-port device, such as a mixer. It could also have more than three ports.

Another exemplary setup employs a combination of tuners to do tuning for a power transistor DUT at non-harmonically related frequencies. In this case, the tuning could with be all passive tuners, all active tuners, or hybrid tuning. One purpose of this might be to prevent an oscillation at a frequency that is not harmonically related to the fundamental frequency being amplified by the DUT. Without the extra tuning, the DUT might oscillate, but changing the impedance at that potential oscillation frequency could prevent the oscillation and allow the DUT to be measured in normal operation.

While the above description has discussed measurements on a DUT, the hybrid active-passive tuner systems and methods have utility in other impedance controlling applications, including for example, system calibration, DC measurements and burn-in operations.

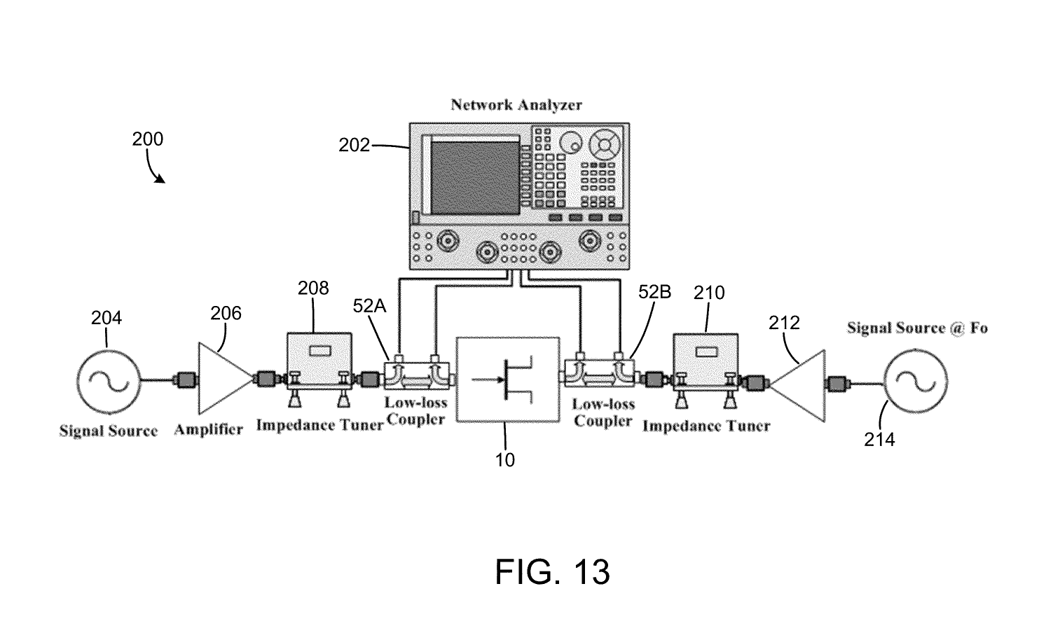

FIG. 13 shows a block diagram of a system 200 with passive tuning on DUT port 1 and hybrid tuning on DUT port 2. The receivers of a network analyzer 202 are connected to dual couplers 52A, 52B on each RF port of the DUT 10 to measure signals at each port. There is one active tuning signal from signal source 204 at the fundamental frequency injected behind the passive tuner 208. Behind the passive tuner means on the side of the passive tuner away from the DUT. The diagram shows a Power Amplifier (PA) 206 amplifying the signal from the input source 204, and another PA 212 amplifying the active tuning signal on port 2 of the DUT. In some cases, the PAs may not be needed if the RF sources put out sufficient power without them. The amount of power required depends on the DUT. A passive tuner 210 is connected at the output side of the setup between the coupler 52B and the PA 212. An active tuning source 214 provides an active tuning signal at the fundamental frequency. The passive tuner 208 may also be optional if the power from the drive source 204 is sufficient to overcome the input mismatch loss at the DUT plane at port 1 of the DUT. The source tuner 208 could also be replaced by a fixed pre-matching circuit. The options for the PAs, the passive source tuner and fixed pre-matching circuit apply to all of the block diagrams of the test setups disclosed herein.

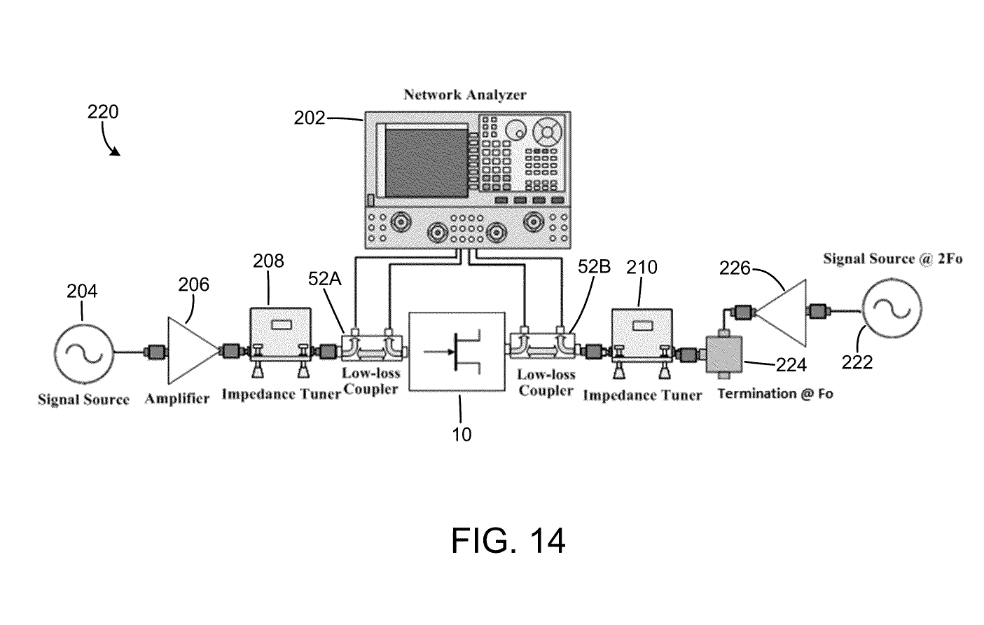

FIG. 14 shows an exemplary setup 220, similar to FIG. 13, with passive tuning on DUT port 1, and hybrid tuning on DUT port 2. In this case, there is a signal separator 224 behind the passive tuner 210 on port 2 that routes the fundamental frequency power from the DUT to a termination, and has a separate path to inject the active tuning signal at the 2nd harmonic frequency from active tuning source 222 and PA 226. An exemplary signal separator is a diplexer that uses filters to separate the fundamental and harmonic signals. This approach is usually the lowest loss at each tuned frequency, and also offers some isolation between frequencies. The isolation between frequencies means that almost all of the fundamental power gets absorbed by the termination. This will protect a smaller PA on the harmonic active tuning source if the required harmonic power is much lower, which is typical of a DUT that would be used for an amplifier. Instead of a diplexer, a combiner/splitter, such as a 3 dB coupler, could be used, but this will normally have higher loss and low isolation. The options for the signal separator apply to all of the setups described herein that include tuning at multiple frequencies.

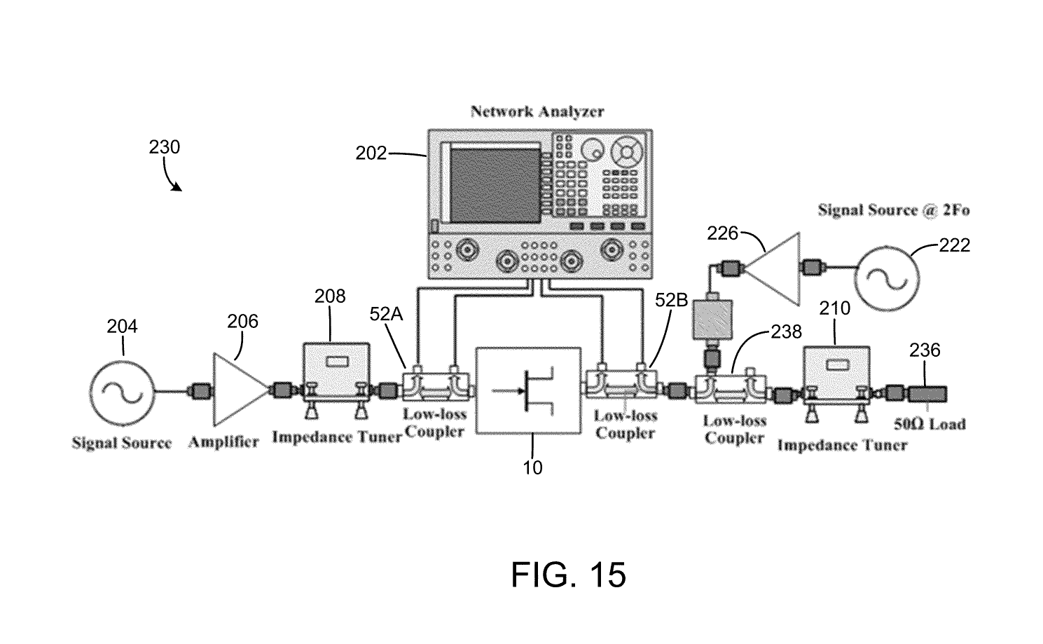

FIG. 15 shows an exemplary setup 230 with passive tuning on DUT port 1, and hybrid tuning on DUT port 2. The setup includes one active tuning signal at the 2nd harmonic frequency injected by signal source 222 and PA 226 in front of the passive tuner 212, through a coupler 238. A 50 ohm load 236 terminates the tuner 212. In front of the passive tuner means on the side of the passive tuner 210 closest to the DUT. In this example, the passive tuner sets the impedance at the fundamental frequency, but may also create a large mismatch loss at the harmonic frequency. Injecting the harmonic active tuning signal in front of the passive tuner 210 adds the coupling factor as loss at the harmonic frequency, but that may be less than the mismatch loss created at the harmonic frequency by the passive tuner. This configuration also means that the harmonic power required is less dependent on the impedance setting of the passive tuner.

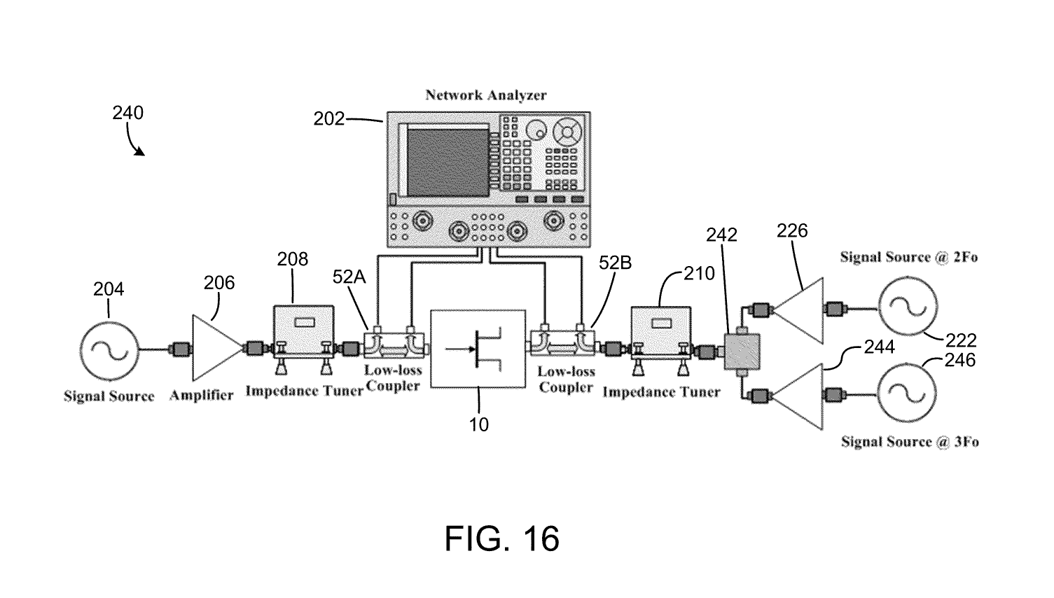

FIG. 16 shows an exemplary setup similar to FIG. 13, except that a signal combiner or separator 242 is added behind the passive tuner 210 on DUT port 2, so that two active tuning sources 222, 246 can be combined to tune two separate frequencies. In this example, the fundamental tuner 210 will tune the impedance at the fundamental frequency, and the active tuning will be done at the 2nd and 3rd harmonic frequencies. The signal combiner or separator could also be expanded to include more active tuning sources, so that more frequencies (such as 4th or 5th harmonics, or even higher order harmonics) could be tuned at the same time. PAs 226 and 244 amplify the second and third harmonic signals from the sources 222, 246.

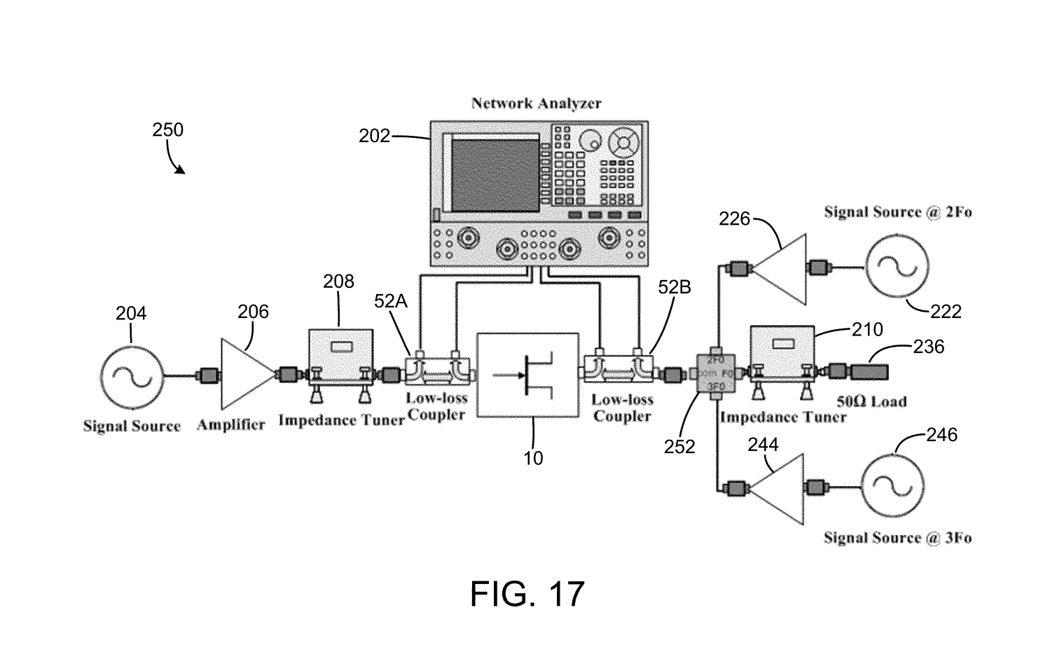

FIG. 17 shows an exemplary setup 250 with passive tuning on DUT port 1, and hybrid tuning on DUT port 2. A signal combiner or separator 252 is placed in front of the passive tuner 210, and two active tuning signals at the 2nd and 3rd harmonic frequencies from sources 222 and 246 through PAs 212 and 244 are injected at that point in the setup. An exemplary signal separator 252 is a 3-way multiplexer (also known as a triplexer) that uses filters to separate the signals at different frequencies. This signal separator could also be expanded to add more active tuning sources to tune other higher order harmonics. It also could be reduced to a 2-way multiplexer (also known as a diplexer) if only one active tuning source is needed.

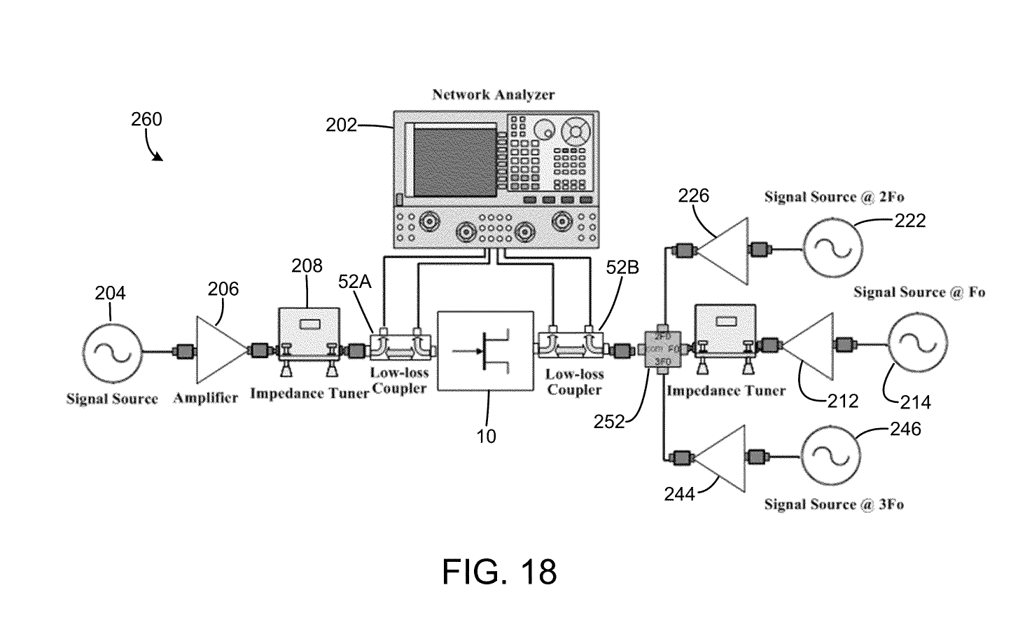

FIG. 18 shows an exemplary setup 260 similar to FIG. 17, except that another active tuning source 214 and PA 212 is added behind the passive tuner 210. The added source in this exemplary setup is at the fundamental frequency to add to the signal reflected by the passive tuner 210, making a higher reflection coefficient possible at the fundamental frequency, which may be needed for some DUTs. Thus, the setup 260 injects one active signal behind the passive tuner 212 at the fundamental frequency, and two additional active tuning signals at the second and third harmonic frequencies are injected in front of the passive tuner 212.

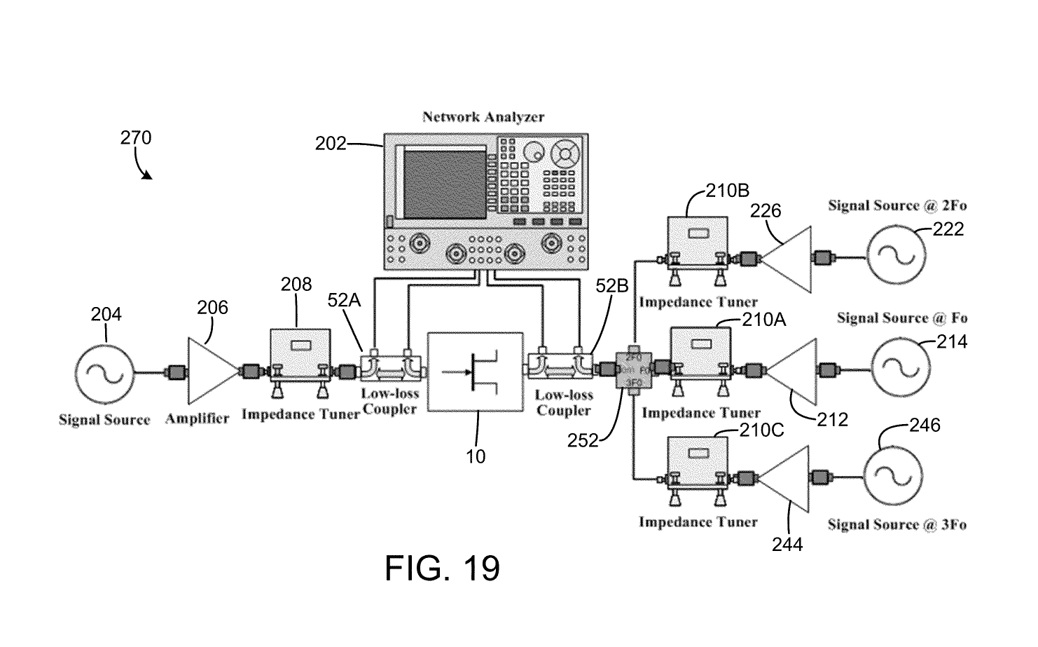

FIG. 19 shows an exemplary test setup 270, with passive tuning on DUT port 1, and hybrid tuning on DUT port 2. In this exemplary hybrid tuning setup, the common port of the triplexer 252 is connected to the back side of the coupler 52B on the DUT port 2, and a combination of a passive tuner (210A, 210B, 210C) and active tuning source (214, 222, 246) and PA (212, 226, 244) is connected to each filtered leg of the triplexer 252. The triplexer 252 separates the three frequencies being tuned, with separate hybrid tuning for each frequency. The passive tuner 210 is set to the fundamental frequency, passive tuner 210B to the second harmonic frequency, and passive tuner 210C to the third harmonic frequency, in this example. Each passive tuner 210A, 210B, 210C will reflect much of the power from the DUT at its frequency, and the active tuning source behind it will expand the matching range at that same frequency, helping to overcome the losses in that frequency path.

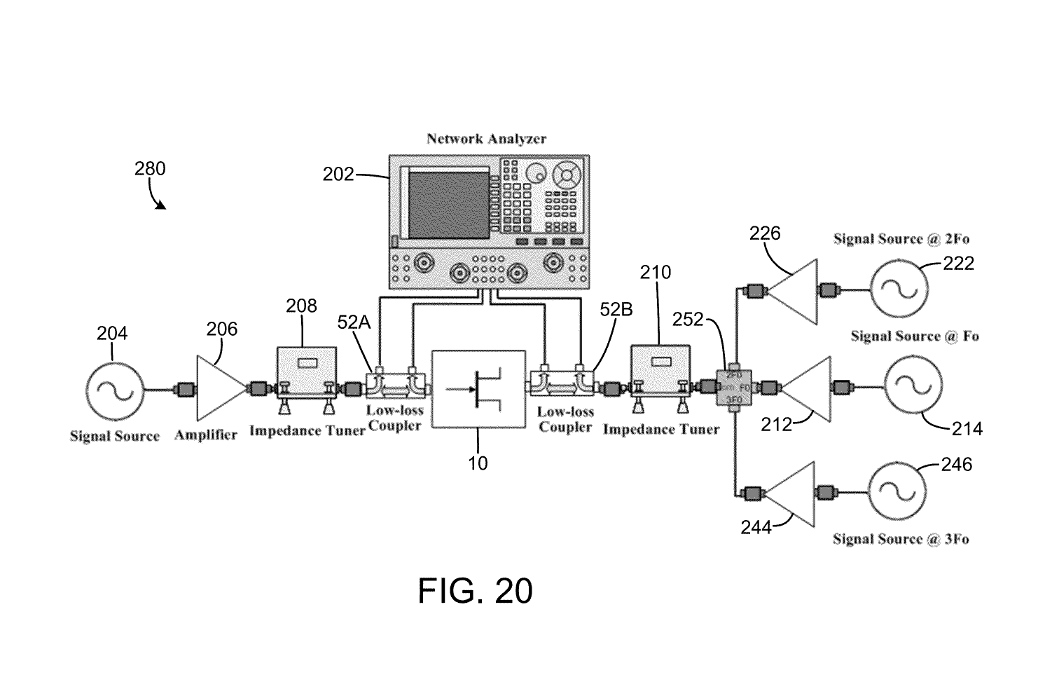

FIG. 20 shows an exemplary setup 280 similar to that of FIG. 19, except that one passive tuner 210 is used on the DUT port 2, and it is connected between the coupler 52B and the common port of the triplexer 252. The passive tuner 210 will normally tune the frequency with the higher power, which often is the fundamental frequency. (However, if the DUT is a frequency multiplier, for example, the highest power would normally be at a harmonic frequency.) The three active tuning sources 214, 222, 246 each tune a different frequency. The setup and multiplexer may also be expanded to include other frequencies, such as higher order harmonics.

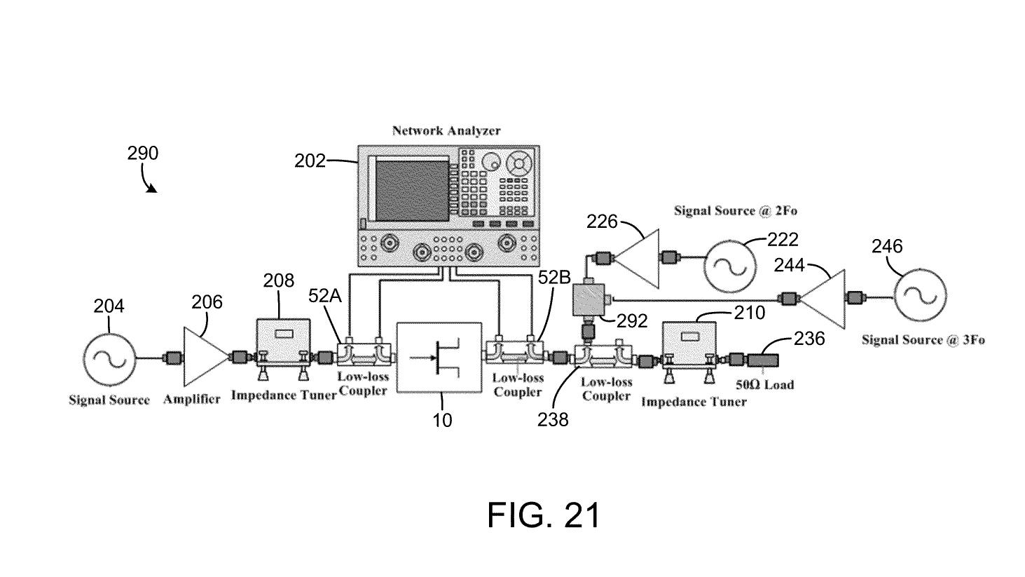

FIG. 21 shows an exemplary setup 290 similar to that of FIG. 15. There is passive tuning on DUT port 1, hybrid tuning on DUT port 2. In this case, two active tuning signals from sources 222 and 246 and PAs 226, 244 are combined by combiner 292 and then injected through coupler 238 in front of the passive tuner 210 to tune the impedance at the 2nd and 3rd harmonic frequencies. The tuner 210 is tuned at the fundamental frequency.

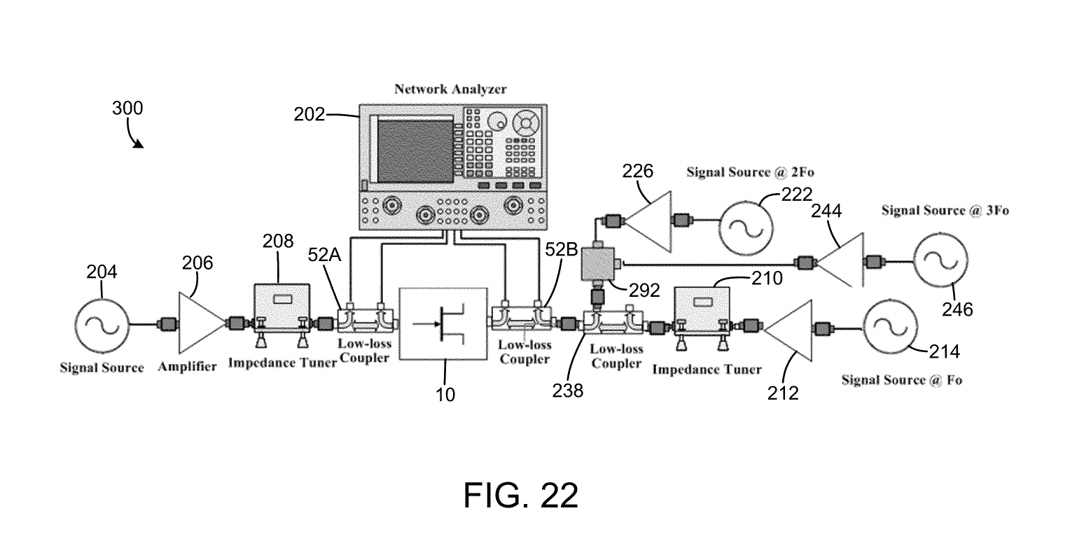

FIG. 22 shows an exemplary setup 300 similar to FIG. 21, except that another active tuning source 214 with PA 212 is added behind the passive tuner 210. The added source in this embodiment is at the fundamental frequency to add to the signal reflected by the passive tuner 210, making a higher reflection coefficient possible at the fundamental, which may be needed for some DUTs. Two active tuning signals are combined and injected in front of the passive tuner 210 to tune the impedance at the second and third harmonic frequencies.

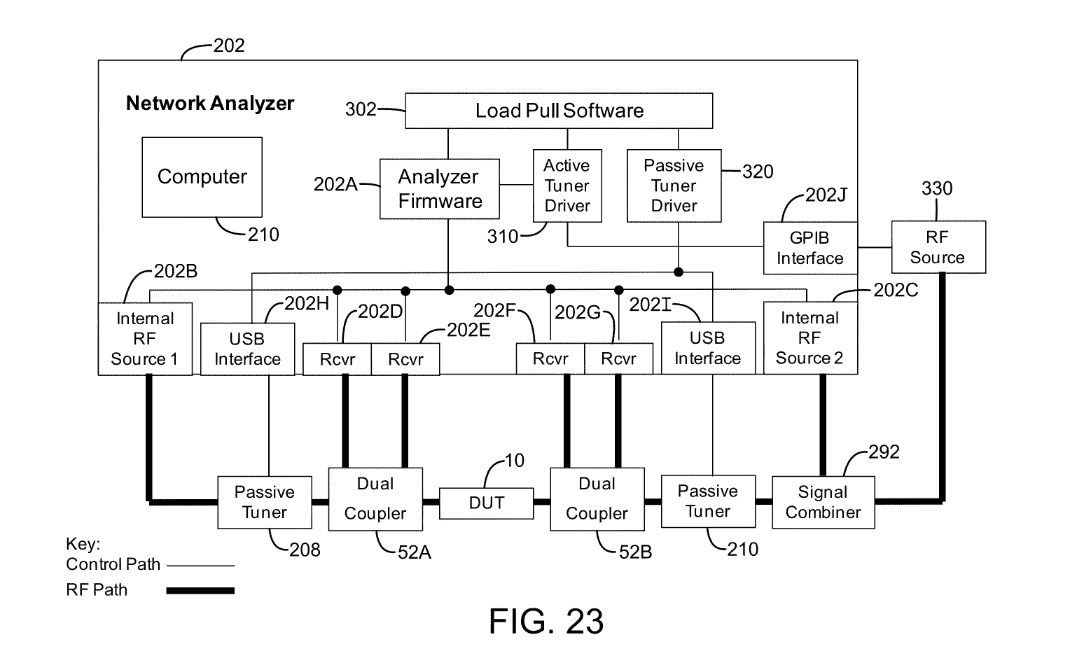

FIG. 23 shows an exemplary block diagram of a control system used for the exemplary test setup in FIG. 17. In this embodiment, the control programs are loaded in the computer 210 of the network analyzer 202, although in other embodiments, the control programs may be implemented on a separate controller or computer. The load pull software 302 is installed into the network analyzer, which has its own controller/computer 210 which can accept and run compatible software programs, and connects to the network analyzer firmware 202A to control the internal RF sources 202B, 202C of the network analyzer, and read data measured with the internal receivers 202D, 202E, 202F, 202G, connected to respective ports of the couplers 52A, 52B of the test setup. The load pull software 302 also uses passive tuner software drivers 320, working through the USB interfaces 202H, 202I to control the passive tuners 208, 210 of the test setup, and active tuner software drivers 310 that connect to the network analyzer firmware 202A to control any internal RF sources 202B, 202C used for active tuning. An active tuning software driver may work through the GPIB interface 202J to control external RF sources such as RF source 330 for active tuning. Other interfaces may also be used to control RF sources, passive tuners, or active tuning. Some instruments may be controlled via TCPIP connections, for example. The control architecture illustrated in FIG. 23 may be expanded or contracted as required to accommodate different numbers of passive tuners or active tuners in the setup. The active tuning sources also may all be external sources leaving all internal (network analyzer) sources for other uses. Also, the load pull software and tuner drivers may be installed into a separate computer instead of inside the network analyzer.

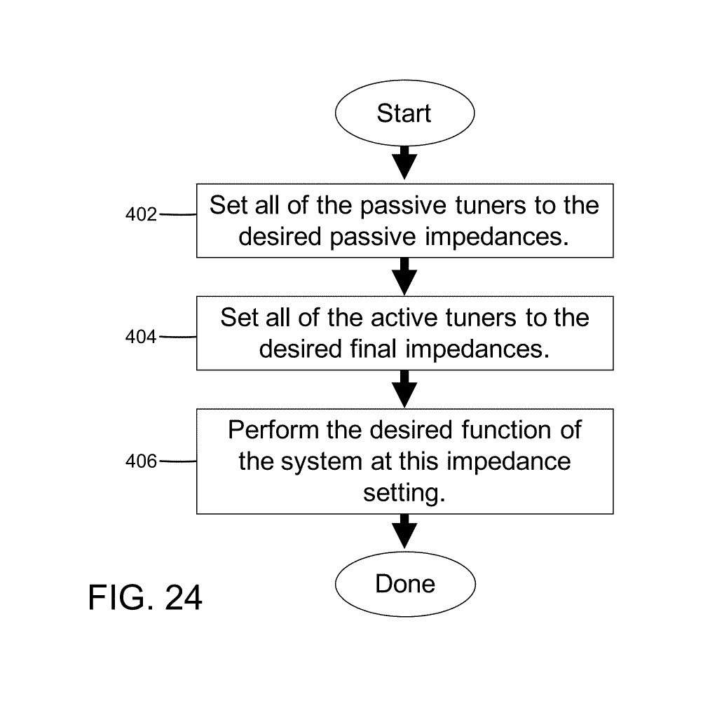

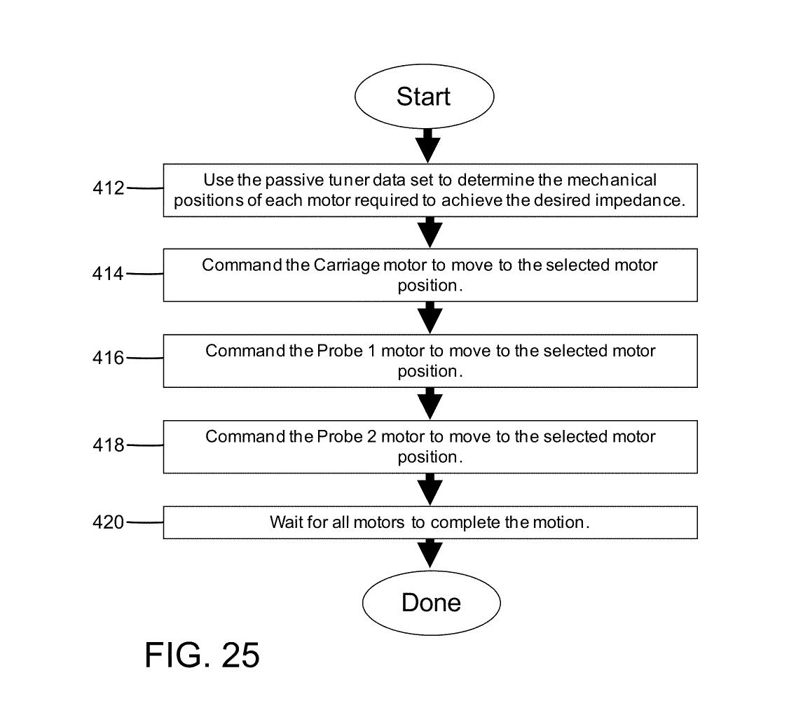

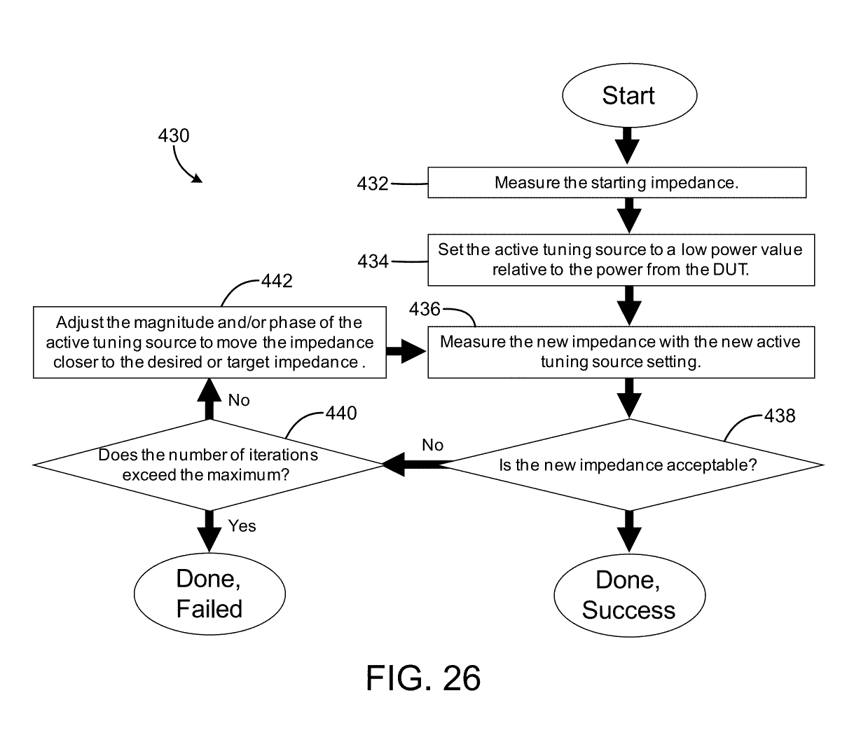

FIG. 24 shows the flow diagram of an exemplary procedure implemented by the loadpull software 302 or other process software for doing hybrid tuning. It includes the following steps:
a) Tune all of the passive tuners in the setup to their desired settings for a target impedance (step 402). Each passive tuner may be set using the exemplary flow diagram of FIG. 25.
b) Tune all of the active tuners in the setup to their desired settings for a target impedance (step 404). Each active tuner may be set using the exemplary flow diagram of FIG. 26.
c) Perform the desired function of the system with the new impedance setting (step 406). For example, in a load pull system, this could include measurement of parameters such as output power, gain, or efficiency.

FIG. 25 shows an exemplary flow diagram of setting one passive tuner that has 3 motors to a target impedance. The exemplary procedure is for an electromechanical impedance tuner including a carriage carrying two probes, typically known as mismatch probes. A carriage motor drives the carriage in a direction parallel to a center conductor to position the carriage (and probes at desired locations along a range of movement. A probe motor for each probe moves the probe along a direction transverse to the center conductor through a range of movement. The target impedance may be different than the target impedance used for any other tuner. The first step 412 is for the main load pull software (302) to determine the position of each motor, such that the combination of motor settings will produce the desired impedance. The next steps 414, 416, 418 are to have the passive tuner software driver 320 command each motor to go to their respective positions. In this case, the carriage motor is commanded to move first, then the first mismatch probe motor, and finally the second mismatch probe motor. The software driver 320 will wait at 420 until all motion is complete before returning. The motors may be moved in multiple steps, and in any sequence. Methods of setting passive tuners are well known in the art.

FIG. 26 shows an exemplary flow diagram of a process 430 of setting one active tuner to a target impedance. This target impedance may be different than the target impedance used for any other tuner. The steps are:
a) Measure the starting impedance (step 432), typically using the network analyzer 202 in the setup.
b) Set the active tuning source to a low power relative to the power from the DUT (step 434). The purpose of this step is to produce a trial move in the impedance, since the relative magnitude and phase of the active tuning source may not be known. The power level then should be small compared to the signal from the DUT, but large enough to change the impedance by an amount that is easily measured.
c) Measure the new impedance with the new active tuning source setting (step 436), and compare it to the desired target impedance (step 438).
d) If the new impedance is acceptable, the tuning process is successfully done. Otherwise, continue to the next step (step 440).
e) Optionally, check the number of iterations (440). If the number of iterations is less than a specified limit, continue to the next step (442). Otherwise, terminate the process and report that the process failed.
f) If the difference between the new impedance and the target impedance is not within tolerance, adjust the magnitude and/or phase of the active tuning source to move the impedance closer to the target impedance (step 442). Then return to step c (436).

It has been found best to set all of the passive tuners in the setup to their desired setting prior to doing any active tuning, although there can be exceptions. For example, it could be necessary to tune the impedance at a first port of a DUT before starting to tune the impedance at a second port of the DUT, in which case a passive tuner on the second port of the DUT might be set or tuned last.

Couplers used for measuring the signals may be connected in front of the passive tuners, as shown in FIG. 13 for example, but they may also be connected behind the passive tuners. Active tuning sources must be connected behind the couplers, such that their signals can be measured but the receivers. This option can be different on different ports of the DUT.

Although the foregoing has been a description and illustration of specific embodiments of the subject matter, various modifications and changes thereto can be made by persons skilled in the art without departing from the scope and spirit of the invention.

What is claimed is:

1. A tuner system that uses at least one passive tuner and at least one active tuner to control one or more impedances at a reference plane or planes, each of the at least one active tuner operating at a target frequency at which the impedance is to be controlled and at least one passive tuner is set to a passive tuner target impedance before each of the at least one active tuner is set to its target impedance.

2. The system of claim 1, wherein each of the at least one passive tuners in the setup are set to their respective target impedances before the at least one active tuner is set to its target impedance.

3. The system of claim 1, wherein the system is configured for measurement of characteristics of a device-under-test (DUT).

4. The system of claim 3, where passive tuning by one of the at least one passive tuners is used on one DUT port at one frequency, and active tuning by one of the at least one active tuners adds to a reflected signal at the same DUT port and frequency.

5. The system of claim 1, where passive tuning by one of the at least one passive tuners is at one target frequency, and active tuning by one of the at least one active tuners is at a different target frequency from the passive tuner target frequency.

6. The system of claim 3, where passive tuning by one of the at least passive tuners is used on one port of a DUT, and active tuning by one of the at least one active tuners is used on another port of the DUT.

7. The system of claim 1, where one of the at least one active tuning sources is connected behind the passive tuner so that signals from the one active tuner passes through the passive tuner.

8. The system of claim 1, where at least one of the active tuners is connected in front of the passive tuner so that signals from the one active tuner do not pass through the passive tuner.

9. The system of claim 1, where said at least one passive tuner and said at least one active tuner control impedances at non-harmonically related frequencies.

10. The system of claim 1, further comprising:
a signal combiner;
the at least one active tuner comprising a first active tuner for generating a first active tuning signal at a first target frequency and a second active tuner for generating a second active tuning signal at a second target frequency;
the signal combiner configured to combine the first active tuning signal and the second active tuning signal.

11. The system of claim 10, wherein the signal combiner is connected between one of the at least one passive tuners and a port of a device-under-test (DUT).

12. The system of claim 10, wherein one of the at least one passive tuners is connected between the signal combiner and a port of a device-under-test (DUT).

13. The system of claim 10, wherein the signal combiner is a filter circuit.

14. The system of claim 3, further comprising:
a signal multiplexer for separating signals of a first frequency and a second frequency;
the signal multiplexer behind a first passive tuner connected relative to a second port of the DUT, and configured to route a fundamental frequency power from the DUT and first passive tuner to a termination, and has a separate path to inject an active tuning signal at a harmonic frequency from a first active tuning source.

15. The system of claim 1, wherein the at least one passive tuners is an electromechanical passive tuner.

16. An impedance tuner system, comprising:
at least one passive impedance tuner;
at least one active impedance tuner, each of said at active impedance tuners configured to generate an active signal;
the at least one passive impedance tuner and the at least one active impedance tuner configured to control one or more impedances at a reference plane or planes of the system;
wherein the system is configured for measurement of characteristics of a device-under-test (DUT)
a control system for controlling the at least one passive impedance tuner and the at least one active tuner, and configured to set the at least one active tuner to operate at an active tuner target frequency at which the impedance is to be controlled and to set the at least one passive tuner to a passive tuner target impedance before the at least one active tuner is set to its target impedance.

17. The system of claim 16, wherein the at least one passive tuners is an electromechanical passive tuner.

18. The system of claim 16, wherein:
a first passive tuner and a first active tuner are configured relative to a first DUT port to provide hybrid impedance tuning on the first DUT port.

19. The system of claim 18, further comprising:
a second passive tuner connected relative to a second port of the DUT to provide passive impedance tuning on the second DUT port.

20. A method for controlling a measurement system on a device-under-test (DUT), the measurement system including at least one passive impedance tuner and at least one active impedance tuner, the method comprising:
a) tune each of the at least one passive tuners to a desired setting for a target impedance for each passive tuner;
b) tune each of the at least one active tuner to a desired setting for a target impedance for each active tuner;
c) perform the desired function of the system with the impedance settings of the at least one passive tuner and the at least one active impedance tuner.
